(19) United States
(12) Patent Application Publication
(10) Pub. No.: US 2023/0352520 A1
(43) Pub. Date: Nov. 2, 2023

(54) WIDE BAND GAP SEMICONDUCTOR DEVICE

(71) Applicant: Infineon Technologies AG, Neubiberg (DE)

(72) Inventor: Thomas Aichinger, Faak am See (AT)

(21) Appl. No.: 18/137,782

(22) Filed: Apr. 21, 2023

(30) Foreign Application Priority Data
Apr. 29, 2022 (DE) 102022110568.7
Mar. 24, 2023 (DE) 102023107534.9

(51) Int. Cl. H01L 29/06; H01L 29/16; H01L 29/739; H01L 29/78

(52) U.S. Cl. CPC H01L 29/063; H01L 29/1608; H01L 29/7397; H01L 29/7813

(57) ABSTRACT

A wide band gap semiconductor device includes a semiconductor body having first and second opposing surfaces along a vertical direction. Trench gate structures extend into the semiconductor body from the first surface and include a gate electrode structure and a gate dielectric structure arranged between the gate electrode structure and the semiconductor body. The gate dielectric structure includes a high-k dielectric layer. A first sidewall of a trench gate structure adjoins a first mesa region. A second sidewall of the trench gate structure adjoins a second mesa region. The first mesa region includes a body region of a first conductivity type adjoining the first sidewall. The second mesa region includes a shielding region of the first conductivity type. A bottom side of the shielding region has a larger first vertical distance to the first surface than a bottom side of the body region in the first mesa region.

### TECHNICAL FIELD

The present disclosure is related to a wide band gap semiconductor device, in particular to a wide band gap semiconductor device including a plurality of trench gate structures.

### BACKGROUND

Technology development of new generations of wide band gap semiconductor devices, e.g. insulated gate field effect transistors (IGFETs) such as metal oxide semiconductor field effect transistors (MOSFETs) or insulated gate bipolar transistors (IGBTs), aims at improving electric device characteristics and reducing costs by shrinking device geometries. Although costs may be reduced by shrinking device geometries, a variety of tradeoffs and challenges have to be met when increasing device functionalities per unit area. For example, reducing the area-specific on-state resistance, RₒₙxA, may have an impact on other electric device characteristics such as, for example, device reliability that may be limited by high electric fields in trench dielectrics, e.g. gate oxide.

There is a need for improving electric characteristics of wide band gap semiconductor devices.

### SUMMARY

An example of the present disclosure relates to a wide band gap semiconductor device including a semiconductor body having a first surface and a second surface opposite to the first surface along a vertical direction. The wide band gap semiconductor device further includes a plurality of trench gate structures extending into the semiconductor body from the first surface. The plurality of trench gate structures includes a gate electrode structure and a gate dielectric structure arranged between the gate electrode structure and the semiconductor body. The gate dielectric structure includes a high-k dielectric layer. The wide band gap semiconductor device further includes a plurality of mesa regions. A first sidewall of a trench gate structure of the plurality of trench gate structures adjoins a first mesa region of the plurality of mesa regions. A second sidewall of the trench gate structure adjoins a second mesa region of the plurality of mesa regions. The first mesa region includes a body region of a first conductivity type adjoining the first sidewall. The second mesa region includes a shielding region of the first conductivity type. A bottom side of the shielding region has a larger first vertical distance to the first surface than a bottom side of the body region in the first mesa region.

Those skilled in the art will recognize additional features and advantages upon reading the following detailed description and on viewing the accompanying drawings.

### BRIEF DESCRIPTION OF THE DRAWINGS

The accompanying drawings are included to provide a further understanding of the embodiments and are incorporated in and constitute a part of this specification. The drawings illustrate embodiments of wide band gap semiconductor devices and together with the description serve to explain principles of the embodiments. Further embodiments are described in the following detailed description and the claims.

FIGS. 1A and 1B are schematic cross-sectional views for illustrating examples wide band gap semiconductor devices including trench gate structures.

FIGS. 2A to 2C are schematic cross-sectional views for illustrating exemplary gate dielectric structures of the wide bandgap semiconductor device.

FIG. 3 is a schematic graph for illustrating exemplary features of a drift structure of a wide bandgap semiconductor device.

### DETAILED DESCRIPTION

In the following detailed description, reference is made to the accompanying drawings, which form a part hereof and in which are shown by way of illustrations specific examples in which semiconductor substrates may be processed. It is to be understood that other examples may be utilized and structural or logical changes may be made without departing from the scope of the present disclosure. For example, features illustrated or described for one example can be used on or in conjunction with other examples to yield yet a further example. It is intended that the present disclosure includes such modifications and variations. The examples are described using specific language, which should not be construed as limiting the scope of the appending claims. The drawings are not scaled and are for illustrative purposes only. Corresponding elements are designated by the same reference signs in the different drawings if not stated otherwise.

The terms “having”, “containing”, “including”, “comprising” and the like are open, and the terms indicate the presence of stated structures, elements or features but do not preclude the presence of additional elements or features. The articles “a”, “an” and “the” are intended to include the plural as well as the singular, unless the context clearly indicates otherwise.

The term “electrically connected” describes a permanent low-resistive connection between electrically connected elements, for example a direct contact between the concerned elements or a low-resistive connection via a metal and/or heavily doped semiconductor material. The term “electrically coupled” includes that one or more intervening element(s) adapted for signal and/or power transmission may be connected between the electrically coupled elements, for example, elements that are controllable to temporarily provide a low-resistive connection in a first state and a high-resistive electric decoupling in a second state.

If two elements A and B are combined using an “or”, this is to be understood to disclose all possible combinations, i.e. only A, only B as well as A and B, if not explicitly or implicitly defined otherwise. An alternative wording for the same combinations is “at least one of A and B” or “A and/or B”. The same applies, mutatis mutandis, for combinations of more than two elements.

Ranges given for physical dimensions include the boundary values. For example, a range for a parameter y from a to b reads as a y b. The same holds for ranges with one boundary value like “at most” and “at least”.

Main constituents of a layer or a structure from a chemical compound or alloy are such elements which atoms form the chemical compound or alloy. For example, silicon (Si) and carbon (C) are the main constituents of a silicon carbide (SiC) layer.

The term “on” is not to be construed as meaning only “directly on”. Rather, if one element is positioned “on” another element (e.g., a layer is “on” another layer or “on” a substrate), a further component (e.g., a further layer) may be positioned between the two elements (e.g., a further layer may be positioned between a layer and a substrate if the layer is “on” said substrate).

An example of the present disclosure relates to a wide band gap semiconductor device. The wide band gap semiconductor device includes a semiconductor body having a first surface and a second surface opposite to the first surface along a vertical direction. The plurality of trench gate structures extends into the semiconductor body from the first surface. The plurality of trench gate structures includes a gate electrode structure and a gate dielectric structure arranged between the gate electrode structure and the semiconductor body. The gate dielectric structure may include a high-k dielectric layer. The wide band gap semiconductor device may further include a plurality of mesa regions. A first sidewall of a trench gate structure of the plurality of trench gate structures may adjoin a first mesa region of the plurality of mesa regions. A second sidewall of the trench gate structure may adjoin a second mesa region of the plurality of mesa regions. The first mesa region may include a body region of a first conductivity type adjoining the first sidewall. The second mesa region may include a shielding region of the first conductivity type. A bottom side of the shielding region may have a larger first vertical distance to the first surface than a bottom side of the body region in the first mesa region.

The wide band gap semiconductor device may be part of an integrated circuit, or may be a discrete semiconductor device or a semiconductor module, for example. The wide band gap semiconductor device may be or may include an insulated gate field effect transistor (IGFET) such as a metal oxide semiconductor field effect transistor (MOSFET) or an insulated gate bipolar transistor (IGBT), for example. The wide band gap semiconductor device may be a vertical semiconductor device having a load current flow between the first surface and the second surface opposite to the first surface. The vertical power semiconductor device may be configured to conduct currents of more than 1 A, or more than 10 A, or more than 30 A, or more than 50 A, or more than 75 A, or even more than 100 A, and may be further configured to block voltages between load electrodes, e.g. between collector and emitter on an IGBT, or between drain and source of a MOSFET, in the range of several hundreds of up to several thousands of volts, e.g. 400 V, 650V, 1.2 kV, 1.7 kV, 3.3 kV, 4.5 kV, 5.5 kV, 6 kV, 6.5 kV, 10 kV. The blocking voltage may correspond to a voltage class specified in a datasheet of the power semiconductor device, for example.

The wide band gap semiconductor device may be based on a semiconductor body from a crystalline wide band gap semiconductor material having a band gap larger than the band gap of silicon, i.e. larger than 1.12 eV. The wide band gap semiconductor material may have a hexagonal crystal lattice and may be silicon carbide (SiC) or gallium nitride (GaN), by way of example. For example, the semiconductor material may be 2H-SiC (SiC of the 2H polytype), 6H-SIC or 15R-SiC. According to an example, the semiconductor material is silicon carbide of the 4H polytype (4H-SiC). The semiconductor body may include or consist of a semiconductor substrate having none, one or more than one semiconductor layers, e.g. epitaxially grown layers, thereon.

The first surface may be a front surface or a top surface of the semiconductor body, and the second surface may be a back surface or a rear surface of the semiconductor body, for example. The semiconductor body may be attached to a lead frame via the second surface, for example. Over the first surface of the semiconductor body, bond pads may be arranged and bond wires may be bonded on the bond pads, for example.

For example, the trench gate structure may be stripe-shaped and the first lateral direction may be a longitudinal direction of the stripe-shaped trench gate structure, for example. The trench gate structure may also have another layout or geometry in a plan view, e.g. hexagonal, square, circular, elliptic. Sidewalls of the trench gate structure may be non-tapered or slightly tapered, for example. In case of slightly tapered sidewalls of the trench gate structure, a channel length may be slightly larger than the vertical extent of a channel region. The taper angle of the trench gate structure may be caused by process technology, e.g. aspect ratio of trench etch processes, and may also be used for maximizing the charge carrier mobility in the channel region which depends from the direction along which channel current flows. Another example for a tapered trench gate structure is a V-shaped trench gate structure.

The gate electrode structure may include one or more conductive material(s), e.g. metal, metal alloys, e.g. Cu, Au, AlCu, Ag, or alloys thereof, metal compounds, e.g. TiN, highly doped semiconductor material such as highly doped polycrystalline silicon. The one or more conductive materials may form a layer stack, for example. The gate electrode structure may be electrically connected to a gate pad, for example. The gate pad and, for example, a first load electrode pad, e.g. a source pad of a MOSFET or an emitter pad of an IGBT, may be part of a wiring area over the wide band gap semiconductor body. The wiring area may include one or more than one, e.g. two, three, four or even more wiring levels. Each wiring level may be formed by a single one or a stack of conductive layers, e.g. metal layer(s). The wiring levels may be lithographically patterned, for example. Between stacked wiring levels, an interlayer dielectric structure may be arranged. Contact plug(s) and/or contact line(s) may be formed in openings of the interlayer dielectric structure to electrically connect parts, e.g. metal lines or contact areas, of different wiring levels to one another.

Each of the mesa regions may be laterally confined by opposite ones of the plurality of trench gate structures, for example.

A part of the body region that adjoins the first sidewall may define a channel region that may be controlled in conductivity by a potential applied to the gate electrode structure, e.g. by field effect. For example, a positive voltage applied to the trench gate structure in an n-channel MOSFET may induce an n-inversion channel in part of a p-doped body region adjoining the first sidewall, for example. The body region may be electrically connected via the first surface, e.g. by a contact plug on a top surface of the body region and/or a groove contact that may extend into the semiconductor body and may be electrically connected to the body region via a sidewall of the groove contact. The channel region part of the body region may include a partial compensation by dopants of the second conductivity type, e.g. n-type dopants in case of a p-doped body region, for adjusting the threshold voltage, for example. The partial compensation may be achieved by a tilted ion implantation through a sidewall of a trench, for example.

The shielding region may form a pn junction with a drift structure of the second conductivity type. The blocking voltage of the wide band gap semiconductor device may be adjusted by an impurity or doping concentration and/or a vertical extension of the drift structure in the semiconductor body. A doping concentration of the drift structure may gradually or in steps increase or decrease with increasing distance to the first surface at least in portions of its vertical extension. According to other examples, the impurity concentration in the drift structure may be approximately uniform. For wide band gap power semiconductor device based on SiC, a mean impurity concentration in the drift structure may be between 5×10¹⁴ cm⁻³ and 1×10¹⁷ cm⁻³, for example in a range from 1×10¹⁵ cm⁻³ to 2×10¹⁶ cm⁻³. A vertical extent of the drift structure may depend on voltage blocking requirements, e.g. a specified voltage class, of the wide band gap semiconductor device. When operating the wide band gap semiconductor device in voltage blocking mode, a space charge region may vertically extend partly or totally through the drift structure depending on the blocking voltage applied to the wide band gap semiconductor device. When operating the wide band gap semiconductor device at or close to the specified maximum blocking voltage, the space charge region may reach or penetrate into a buffer region of the drift structure that is configured to prevent the space charge region from further reaching to a contact of a second load electrode at the second surface. The second load electrode may be a collector electrode of an IGBT, or a drain electrode of a MOSFET, for example.

For realizing a desired current carrying capacity, the wide band gap semiconductor device may be designed by a plurality of parallel-connected wide band gap semiconductor device cells. The parallel-connected wide band gap semiconductor device cells may, for example, be wide band gap semiconductor device cells formed in the shape of a strip or a strip segment. Of course, the wide band gap semiconductor device cells can also have any other shape, e.g. circular, elliptical, polygonal such as hexagonal or octahedral. The wide band gap semiconductor device cells may be arranged in an active area of the semiconductor body. The active area may be an area where an emitter region of an IGBT (or a source region of a MOSFET) and a collector region of an IGBT (or a drain region of a MOSFET) are arranged opposite to one another along the vertical direction. In the active area, a load current may enter or exit the semiconductor body of the wide band gap semiconductor device, e.g. via contact plugs on the first surface of the semiconductor body. The wide band gap semiconductor device may further include an edge termination area that may include a termination structure. In a blocking mode or in a reverse biased mode of the wide band gap semiconductor device, the blocking voltage between the active area and a field-free region laterally drops across the termination structure. The termination structure may have a higher or a slightly lower voltage blocking capability than the active area. The termination structure may include a junction termination extension (JTE) with or without a variation of lateral doping (VLD), one or more laterally separated guard rings, or any combination thereof, for example.

Provision of the shielding region and the gate dielectric structure including the high-k dielectric layer may allow for increasing the gate-to-source capacitance (CGS) without degrading reliability of the gate dielectric structure in the on-state of the wide band gap semiconductor device. This may allow for reducing the area-specific on-state resistance, RₒₙxA, and the drain-induced barrier lowering (DIBL). For example, the reduced DIBL owing to the high-k dielectric layer in the gate dielectric may allow for using a shorter MOS channel (e.g. in the range of 100 nm to 300 nm). In view of the high-k dielectric layer, shielding effort of the gate dielectric layer by the shielding region may be reduced compared with SiO₂ gate dielectrics. This may allow for reducing the on-state resistance component ascribed to the so-called JFET (junction field effect transistor) that is based on the shielding regions. Shrinking vertical and/or lateral dimensions of the shielding regions may allow for smaller cell pitches, for example. Compared with trench transistors based on SiO₂ gate dielectrics and shielding regions, a number of technical benefits may be achieved, including, inter alia, avoidance of deep implants requiring high ion implantation energies since higher electric field strengths may be allowed closer to the gate dielectric structure, reduced lateral distances of the shielding regions enable cell shrinkage, lower ion implantation doses for the body regions due to a reduced DIBL and/or negative built-in charge in the high k dielectric layer enables a higher channel mobility due to less ion impurity scattering in on-state. A lower DIBL may be achieved in view of the higher gate-to-source capacitance due to the high-k dielectric layer, higher ion implantation doses for the current spread region may be achieved in view of higher electric fields that are allowed close to the gate dielectric layer in view of the high-k dielectric layer. The tolerance for higher electric fields close to the gate dielectric layer may allow for lowering all ion implantation energies/depths/doses of the first conductivity type that are typically required to form a JFET-like shielding region of a trench MOSFET, thereby reducing the JFET resistance and allowing for a significant manufacturing cost and complexity reduction as well as for a pitch reduction (shallower implants typically have less “lateral straggling”). At the same time higher ion implantation doses and/or energies of the second conductivity type can be used to form an optimized current spread region that allows for better current spreading and further reduction of RₒₙxA.

For example, the dielectric structure (abbreviated DS) may replace a known SiO₂ gate dielectric of a SiC MOSFET and may fulfil one or more, e.g. all, of the following properties: i) a relative permittivity: ϵ_{r,AGI}»ϵ_{r,SiO2}, e.g. ϵ_{r,AGI}≥ϵ_{r,SiC}; ii) a conduction band offset: E_{C,DS}−E_{C,SiC}»0, e.g. E_{C,ADS}−E_{C,SiC}≥1 eV; iii) a valence band offset: E_{V,SiC}−E_{V,DS}»0, e.g. E_{V,SiC}−E_{V,DS}≥1 eV; iv) a break down strength E_{BD,DS}>E_{BD,SIC}, e.g. E_{BD,DS}≥4 MV/cm; v) be non-ferroelectric. Property (i) enables the benefits of (1) increasing the gate-source capacitance substantially without degrading the gate dielectric reliability in an on-state, thereby reducing the channel resistance and the drain-induced barrier lowering (DIBL), and of (2) reducing the shielding effort of the gate dielectric substantially without degrading the gate dielectric reliability in off-state, thereby reducing the JFET resistance and allowing for smaller pitches. Properties (ii), (iii) and (iv) qualify the material of the dielectric structure as a gate insulator for SiC. Materials that fulfill the upper properties are, for example, Al₂O₃, HfO₂, ZrO₂, AlN. Property (v) ensures that the permittivity does not change with applied gate bias.

For example, the high-k dielectric layer of the wide band gap semiconductor device may include at least one of Al₂O₃, HfO₂, ZrO₂, AlN, alumosilicate AlSiOₓ, silicon La- or Si-doped HfO₂, TiO₂, Y₂O₃, or Si₃N₄.

For example, the dielectric structure may further include a first dielectric layer arranged between the high-k dielectric layer and the body region. The first dielectric layer may have a dielectric constant that is smaller than the dielectric constant of the high-k dielectric layer, and is equal to or larger than the dielectric constant of SiO₂. For example, the first dielectric layer may include at least one of SiO₂, AlN, or Si₃N₄, for example.

For example, the first dielectric layer may be a first SiO₂ layer. A thickness of the high-k dielectric layer may be, by a factor ranging from 2 to 200, larger than a first thickness of the first dielectric layer. This may allow for taking benefit of interface properties between SiO₂ and the wide band gap semiconductor body, e.g. SiC, while making use of the high permittivity of the high-k dielectric layer for reducing the channel resistance and JFET shielding.

For example, an interface between the first SiO₂ layer and the semiconductor body, e.g. SiC, may be passivated by nitrogen. Nitrogen passivation may be achieved, for example, by forming a thin SiO₂ layer on the semiconductor body followed by annealing in nitric oxide, NO. As an alternative or in addition, nitrogen passivation may also be achieved, for example, by depositing a thin SiO₂ layer on the semiconductor body in nitric oxide atmosphere and afterwards passivate the interface of this layer to the semiconductor body in a nitric oxide atmosphere.

As an alternative or in addition, nitrogen passivation may also be achieved, for example, by oxidizing the silicon carbide surface in a nitrogen containing atmosphere, e.g. nitric-oxide NO or nitrous oxide N₂O. To further reduce the thickness of the first nitrogen passivated oxide layer, a wet oxide etching, e.g. a solution containing hydrofluoric acid, can be used after oxidizing the silicon carbide surface in a nitrogen containing atmosphere. After wet etch only a very thin nitrogen and oxygen containing layer may remain at the SiC/SiO₂ interface.

For example, the first thickness may range from 1 nm to 10 nm. The first dielectric layer may have a thickness corresponding to a small number of monolayers, for example. In some examples, the first dielectric layer may have a first thickness below 1 nm.

For example, the dielectric structure may further include a second dielectric layer arranged between the high-k dielectric layer and the gate electrode structure. The second dielectric layer may have a dielectric constant that is smaller than the dielectric constant of the high-k dielectric layer, and is equal to or larger than the dielectric constant of SiO₂. For example, the second dielectric layer may include at least one of SiO₂, AlN, or Si₃N₄, for example.

For example, the second dielectric layer may be a second SiO₂ layer. A thickness of the high-k dielectric layer may be, by a factor ranging from 2 to 200, larger than a each of a first thickness of the first SiO₂ layer, or a second thickness of the second SiO₂ layer, or a sum of the first thickness and the second thickness. This relation between thicknesses may depend on the breakdown voltage and permittivity of each dielectric layer in the stack and may be optimized for a targeted reliability and a low channel resistance, thereby taking the breakdown voltage and the high permittivity of the high-k dielectric layer and its ratios to the other dielectric layers of lower permittivity into account. This may allow for taking further benefit of interface properties between SiO₂ and the wide band gap semiconductor body, e.g. SiC, while making use of the high permittivity of the high-k dielectric layer for reducing the channel resistance.

For example, the shielding region may adjoin at least part of the second sidewall and part of a bottom side of the trench gate structure. The first vertical distance may range from 101% to 150% of a second vertical distance from a bottom side of the trench gate structure to the first surface. As an alternative or in addition, a bottom side of a pn junction between the shielding region and a drift structure may have a vertical distance to the bottom side of the trench gate structure that ranges from 10 nm to 500 nm, for example. This may allow for an improvement with respect to shrinking cell layout dimensions and reducing the RₒₙxA compared with cell layouts having deeper shielding regions and SiO₂ gate dielectrics.

For example, the shielding region may adjoin at least part of the second sidewall. The first vertical distance may range from 60% to 100% of a second vertical distance from a bottom side of the trench gate structure to the first surface. For example, the first vertical distance may range from an end of a channel region, e.g. a bottom side of the body region, to the bottom side of the trench gate structure.

For example, at a vertical level of a bottom side of a source region of the second conductivity type, a width of the shielding region may range from 60% to 90% of a width of the second mesa region. In addition or as an alternative, the width of the shielding region may range from 50 nm to 300 nm, for example. Since a depth of the shielding region may be decreased with respect to shielding regions of trench MOSFETs having a SiO₂ gate oxide, lateral straggling during ion implantation of the shielding regions may be deceased. This may allow for a better control of horizontal implantation profiles (“more box-like”) and, as a consequence, allow for a further reduction of cell layout dimensions, for example.

For example, the second mesa region may include the body region adjoining the second sidewall of the trench gate structure. A gate electrode of the trench gate structure may be configured to control a channel conductivity, e.g. by field effect, at opposite sidewalls of the trench gate structure, for example.

For example, the shielding region may be laterally confined by parts of the body region. Parts of the body regions adjoining the sidewall a trench gate structure may define channel regions that may be controlled in conductivity via a potential applied to the gate electrode of the trench gate structure, for example.

For example, the first vertical distance may range from 101% to 150% of a second vertical distance from a bottom side of the trench gate structure to the first surface. As an alternative or in addition, a bottom side of a pn junction between the shielding region and a drift structure may have a vertical distance to the bottom side of the trench gate structure that ranges from 10 nm to 500 nm, for example. This may allow for an improvement with respect to shrinking cell layout dimensions and reducing the RₒₙxA compared with cell layouts having deeper shielding regions and SiO₂ gate dielectrics.

For example, the wide band gap semiconductor device may further comprise a drift region of a second conductivity type, and a current spread region of the second conductivity type. The current spread region may be arranged between the drift region and the body region and may have a doping concentration, averaged along a vertical extent of the current spread region, that is larger, by a factor ranging from 10 to 1000, than a doping concentration averaged along a part of the drift region. The part of the drift region may adjoin the current spread region and may have a vertical extent corresponding to the vertical extent of the current spread region. The current spread region and the drift region may be parts of a drift structure, for example.

For example, the trench gate structures may extend in parallel along a longitudinal direction. The shielding region may have a plurality of sub-regions spaced from each other along the longitudinal direction. A lateral spacing between the sub-regions along the longitudinal direction may be constant or varying, for example. Likewise, a lateral dimension of the sub-regions along the longitudinal direction may be constant or varying, for example.

For example, a vertical doping profile of the shielding region may be configured to set a peak of an electric field strength at 99% of an electric breakdown voltage between load electrodes, e.g. source and drain, of the wide band gap semiconductor device at or close to an interface between the trench dielectric structure and the semiconductor body at a bottom side or corner of the trench gate structure.

The examples and features described above and below may be combined.

Some of the above and below examples are described in connection with a silicon carbide substrate. Alternatively, a wide band gap semiconductor substrate, e.g. a wide band gap wafer, may be processed, e.g. comprising a wide band gap semiconductor material different from silicon carbide. The wide band gap semiconductor wafer may have a band gap larger than the band gap of silicon (1.12 eV). For example, the wide band gap semiconductor wafer may be a silicon carbide (SiC) wafer, or gallium arsenide (GaAs) wafer, or a gallium nitride (GaN) wafer.

More details and aspects are mentioned in connection with the examples described above or below. Processing a wide band gap semiconductor wafer may comprise one or more optional additional features corresponding to one or more aspects mentioned in connection with the proposed concept or one or more examples described above or below.

The description and drawings merely illustrate the principles of the disclosure. Furthermore, all examples recited herein are principally intended expressly to be only for illustrative purposes to aid the reader in understanding the principles of the disclosure and the concepts contributed by the inventor(s) to furthering the art. All statements herein reciting principles, aspects, and examples of the disclosure, as well as specific examples thereof, are intended to encompass equivalents thereof.

In the following, further examples of field effect transistors, FETs, are explained in connection with the accompanying drawings. Functional and structural details described with respect to the examples above shall likewise apply to the exemplary embodiments illustrated in the figures and described further below. In the illustrated examples, the first conductivity is p-type and the second conductivity type is n-type for an n-channel FET. However, the first conductivity type may also be n-type and the second conductivity type may be p-type for a p-channel FET.

Details with respect to structure, or function, or technical benefit of features described above likewise apply to the examples below and vice versa.

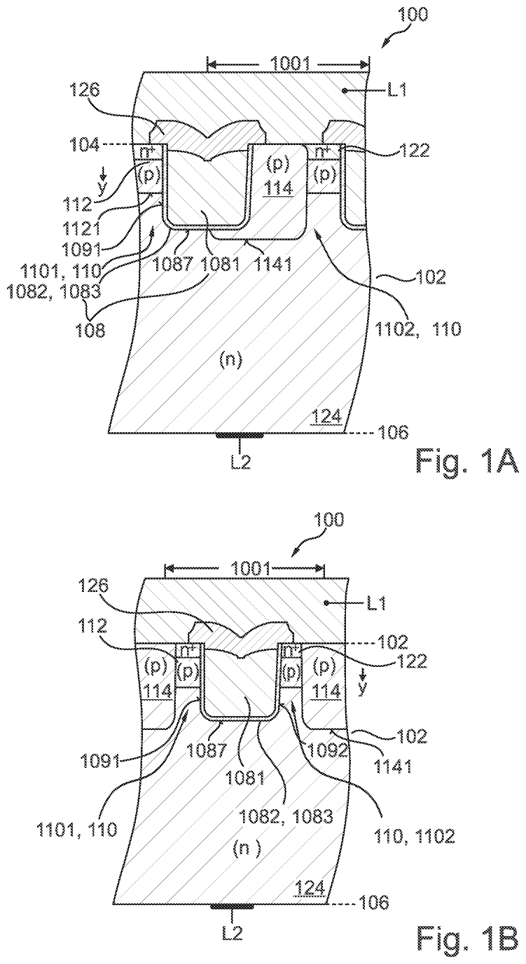

FIG. 1A schematically and exemplarily shows a partial cross-sectional view of an active area of a wide band gap semiconductor device 100. The wide band gap semiconductor device 100 may be a vertical power semiconductor device that further includes an edge termination area that at least partially surrounds the active area (not illustrated in FIG. 1A). The wide band gap semiconductor device 100 includes a SiC semiconductor body 102 having a first surface 104 and a second surface 106 opposite to the first surface 104 along a vertical direction y. A plurality of trench gate structures 108 extend into the semiconductor body 102 from the first surface 104. The plurality of trench gate structures 108 include a gate electrode structure 1081 and a gate dielectric structure 1082 arranged between the gate electrode structure 1081 and the semiconductor body 102. The gate dielectric structure 1082 includes a high-k dielectric layer 1083. The wide band gap semiconductor device 100 further includes a plurality of mesa regions 110. A first sidewall 1091 of a trench gate structure 108 of the plurality of trench gate structures 108 adjoins a first mesa region 1101 of the plurality of mesa regions 110. A second sidewall 1092 of the trench gate structure 108 adjoins a second mesa region 1102 of the plurality of mesa regions 110. The first mesa region 1101 includes a p-doped body region 112 adjoining the first sidewall 1091. The second mesa region 1102 includes a p-doped shielding region 114, and a bottom side 1141 of the shielding region 114 has a larger first vertical distance to the first surface 104 than a bottom side 1121 of the body region 112 in the first mesa region 1101. The bottom side 1121 may be located below a bottom side 1087 of the trench gate structure 108 as is illustrated in FIG. 1A, or may be located above the above the bottom side 1087 (not illustrated in FIG. 1A). The shielding region may be continuous along a lateral direction running perpendicular to the drawing plane of FIG. 1A, or may be sub-divided into shielding sub-regions spaced from one another along the lateral direction running perpendicular to the drawing plane of FIG. 1A. The first mesa region 1101 further includes an n⁺-doped source or emitter region 122 adjoining the first sidewall 1091. The wide band gap semiconductor device 100 further includes an n-doped drift structure 124 between the body region 112/shielding region 114 and the second surface 106. The drift structure 124 may include one or more sub-regions that may differ with respect to doping concentration and vertical extent, for example (not illustrated in FIG. 1A). Sub-regions of the drift structure 124 may include, inter alia, an n⁻-doped drift region, an n-doped current spread region between the drift region and the second surface 106. An n⁺-doped drain contact region (for wide band gap MOSFETs) or a p⁺-doped collector region (for wide band gap IGBTs) is arranged between the drift structure 124 and the second surface 106 (not illustrated in FIG. 1A).

A first load electrode L1 is electrically connected to the source region 122, the shielding region 114 and the body region 112 via the first surface 104 of the wide band gap semiconductor body 102. A second load electrode L2 is electrically connected to the drift structure 124 via the second surface 106 of the semiconductor body 102. A blocking voltage of the wide band gap semiconductor device 100 between the first and second load electrodes L1, L2 may be determined by a breakdown voltage of a pn junction between the shielding region 112 and the drift structure 124, for example.

The first load electrode L1 and the gate electrode structure 1081 are electrically insulated by an intermediate dielectric 126.

In the example of FIG. 1A, the wide band gap semiconductor device 100 includes a channel region at one sidewall of opposite sidewalls of the trench gate structures 108. The channel region is defined by a part of the body region 112 adjoining the trench gate structure 108.

FIG. 1B schematically and exemplarily shows a partial cross-sectional view of an active area of another example of a wide band gap semiconductor device 100 having a channel region at opposite sidewalls of the trench gate structure 108. In the example illustrated in FIG. 1B, the second mesa region 1102 includes the body region 112 adjoining the second sidewall 1092 of the trench gate structure 108.

For realizing a desired current carrying capacity of the wide band gap semiconductor devices 100 illustrated in FIGS. 1A and 1B, the wide band gap semiconductor device 100 may be designed by a plurality of parallel-connected wide band gap semiconductor device cells 1001. The parallel-connected wide band gap semiconductor device cells 1001 may, for example, be wide band gap semiconductor device cells formed in the shape of a strip or a strip segment.

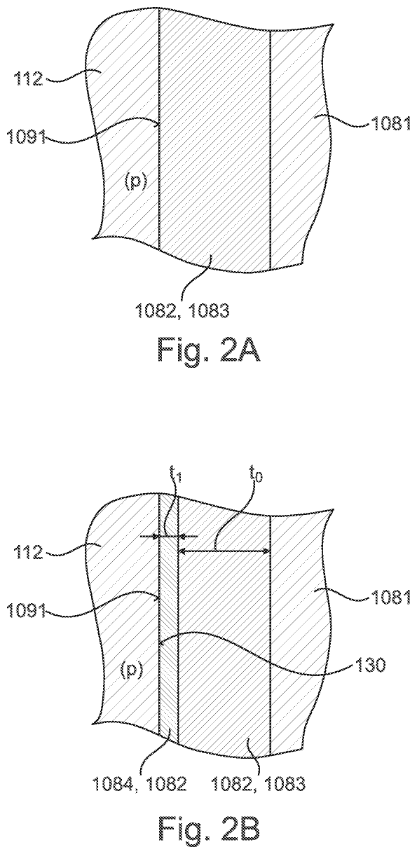

FIGS. 2A to 2C schematically and exemplarily show partial cross-sectional views for illustrating examples of the gate dielectric structure 1082 arranged between the body region 112 and the gate electrode structure 1081.

Referring to the cross-sectional view of FIG. 2A, the gate dielectric structure 1082 between the body region 112 and the gate electrode structure 1081 consists of the high-k dielectric layer 1083.

Referring to the cross-sectional view of FIG. 2B, the gate dielectric structure 1082 between the body region 112 and the gate electrode structure 1081 includes the high-k dielectric layer 1083 and a first dielectric layer 1084 arranged between the high-k dielectric layer 1083 and the body region 112. The first dielectric layer 1084 may have a dielectric constant that is smaller than the dielectric constant of the high-k dielectric layer 1083, and is equal to or larger than the dielectric constant of SiO₂. For example, the first dielectric layer 1084 may include at least one of SiO₂, AlN, or Si₃N₄, for example. For example, the first dielectric layer 1084 may be a first SiO₂ layer. A thickness t0 of the high-k dielectric layer 1083 may be, by a factor ranging from 2 to 200, larger than a first thickness t1 of the first dielectric layer 1084. An interface 130 between the first SiO₂ layer 1084 and the semiconductor body 102, e.g. SiC, may be passivated by nitrogen.

Referring to the cross-sectional view of FIG. 2C, the gate dielectric structure 1082 between the body region 112 and the gate electrode structure 1081 includes, in addition to the high-k dielectric layer 1083 and the first dielectric layer 1084 arranged between the high-k dielectric layer 1083 and the body region 112, a second dielectric layer 1085 arranged between the high-k dielectric layer 1083 and the gate electrode structure 1081. The second dielectric layer 1085 may have a dielectric constant that is smaller than the dielectric constant of the high-k dielectric layer 1083, and is equal to or larger than the dielectric constant of SiO₂. For example, the second dielectric layer 1085 may include at least one of SiO₂, AlN, or Si₃N₄, for example. The thickness of the high-k dielectric layer 1083 may be, by a factor ranging from 2 to 200, larger than each single dielectric layer with lower permittivity or the sum, e.g. larger than the first thickness t1 of the first SiO₂ layer 1084 or a second thickness t2 of the second SiO₂ layer 1085, or a sum thereof.

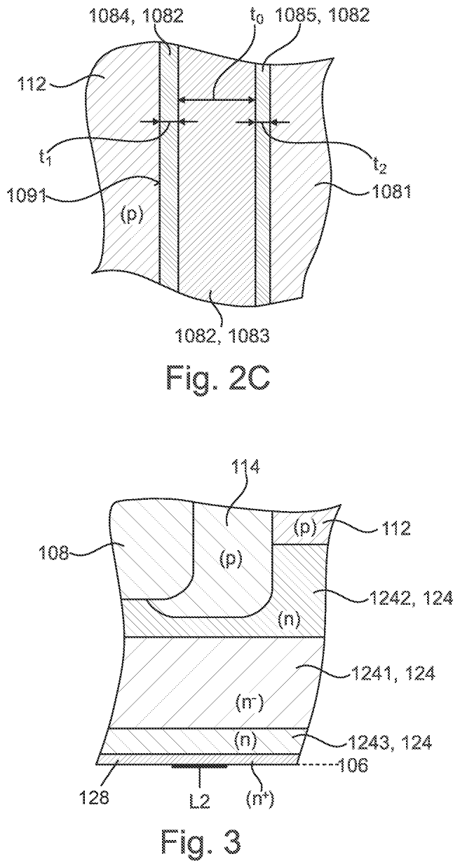

FIG. 3 schematically and exemplarily shows a partial cross-sectional view of an active area of a wide band gap semiconductor device 100 for illustrating exemplary sub-regions of the drift structure 124. The drift structure 124 may include an n--doped drift region 1241, and an n-doped current spread region 1242. The current spread region 1242 is arranged between the drift region 1241 and the body region 112 and has a doping concentration, averaged along a vertical extent of the current spread region 1242, that is larger, e.g. by a factor ranging from 10 to 1000, than a doping concentration averaged along a part of the drift region 1241. The part of the drift region 1241 may adjoin the current spread region 1242 and may have a vertical extent corresponding to the vertical extent of the current spread region 1242, for example. The drift structure 124 may further include an n-doped buffer region 1243 between the drift region 1241 and the second surface 106. The drift structure 124 is electrically connected to the second load electrode L2, e.g. a drain electrode, via an n+-doped drain contact region 128 at the second surface 106.

The aspects and features mentioned and described together with one or more of the previously described examples and figures, may as well be combined with one or more of the other examples in order to replace a like feature of the other example or in order to additionally introduce the feature to the other example.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A wide band gap semiconductor device, comprising:
a semiconductor body having a first surface and a second surface opposite to the first surface along a vertical direction;
a plurality of trench gate structures extending into the semiconductor body from the first surface, the plurality of trench gate structures including a gate electrode structure and a gate dielectric structure arranged between the gate electrode structure and the semiconductor body, the gate dielectric structure including a high-k dielectric layer;
a plurality of mesa regions,
wherein a first sidewall of a trench gate structure of the plurality of trench gate structures adjoins a first mesa region of the plurality of mesa regions, and a second sidewall of the trench gate structure adjoins a second mesa region of the plurality of mesa regions,
wherein the first mesa region includes a body region of a first conductivity type adjoining the first sidewall,
wherein the second mesa region includes a shielding region of the first conductivity type,
wherein a bottom side of the shielding region has a larger first vertical distance to the first surface than a bottom side of the body region in the first mesa region.

2. The wide band gap semiconductor device of claim 1, wherein the high-k dielectric layer includes at least one of Al₂O₃, ZrO₂, HfO₂, AlN, alumisilicate AlSiOₓ, silicon doped HfO₂, TiO₂, Y₂O₃ or Si₃N₄.

3. The wide band gap semiconductor device of claim 1, wherein the dielectric structure further includes a first dielectric layer arranged between the high-k dielectric layer and the body region, the first dielectric layer having a dielectric constant that is smaller than the dielectric constant of the high-k dielectric layer and is equal to or larger than the dielectric constant of SiO₂.

4. The wide band gap semiconductor device of claim 3, wherein the first dielectric layer is a first SiO₂ layer, and wherein a thickness of the high-k dielectric layer is, by a factor ranging from 2 to 200, larger than a first thickness of the first dielectric layer.

5. The wide band gap semiconductor device of claim 4, wherein an interface between the first SiO₂ layer and the semiconductor body is passivated by nitrogen.

6. The wide band gap semiconductor device of claim 5, wherein the first thickness ranges from 1 nm to 10 nm.

7. The wide band gap semiconductor device of claim 5, wherein the first thickness is smaller than 1 nm.

8. The wide band gap semiconductor device of claim 5, wherein the dielectric structure further includes a second dielectric layer arranged between the high-k dielectric layer and the gate electrode structure, the second dielectric layer having a dielectric constant that is smaller than the dielectric constant of the high-k dielectric layer and is equal to or larger than the dielectric constant of SiO₂.

9. The wide band gap semiconductor device of claim 8, wherein the second dielectric layer is a second SiO₂ layer, and wherein a thickness of the high-k dielectric layer is, by a factor ranging from 2 to 200, larger than each of a first thickness of the first SiO₂ layer, or a second thickness of the second SiO₂ layer, or a sum of the first thickness and the second thickness.

10. The wide band gap semiconductor device of claim 1, wherein the shielding region adjoins at least part of the second sidewall and part of a bottom side of the trench gate structure, and wherein the first vertical distance ranges from 101% to 150% of a second vertical distance from a bottom side of the trench gate structure to the first surface.

11. The wide band gap semiconductor device of claim 10, wherein at a vertical level of a bottom side of a source region of the second conductivity type, a width of the shielding region ranges from 60% to 90% of a width of the second mesa region.

12. The wide band gap semiconductor device of claim 1, wherein the shielding region adjoins at least part of the second sidewall, and wherein the first vertical distance ranges from 60% to 100% of a second vertical distance from a bottom side of the trench gate structure to the first surface.

13. The wide band gap semiconductor device of claim 12, wherein at a vertical level of a bottom side of a source region of the second conductivity type, a width of the shielding region ranges from 60% to 90% of a width of the second mesa region.

14. The wide band gap semiconductor device of claim 1, wherein the second mesa region includes the body region adjoining the second sidewall of the trench gate structure.

15. The wide band gap semiconductor device of claim 14, wherein the shielding region is laterally confined by parts of the body region.

16. The wide band gap semiconductor device of claim 14, wherein the first vertical distance ranges from 101% to 110% of a second vertical distance from a bottom side of the trench gate structure to the first surface.

17. The wide band gap semiconductor device of claim 1, further comprising:
a drift region of a second conductivity type; and
a current spread region of the second conductivity type,
wherein the current spread region is arranged between the drift region and the body region and has a doping concentration, averaged along a vertical extent of the current spread region, that is larger, by a factor ranging from 10 to 1000, than a doping concentration averaged along a part of the drift region,
wherein the part of the drift region adjoins the current spread region and has a vertical extent corresponding to the vertical extent of the current spread region.

18. The wide band gap semiconductor device of claim 1, wherein the trench gate structures extend in parallel along a longitudinal direction, and wherein the shielding region has a plurality of sub-regions spaced from each other along the longitudinal direction.

19. The wide band gap semiconductor device of claim 1, wherein the semiconductor body is a 4H-SiC semiconductor body.

20. The wide band gap semiconductor device of claim 1, wherein a vertical doping profile of the shielding region is configured to set a peak of an electric field strength at 99% of an electric breakdown voltage between load electrodes of the wide band gap semiconductor device at or close to an interface between the trench dielectric structure and the semiconductor body at a bottom side of the trench gate structure.

21. The wide band gap semiconductor device of claim 1, wherein the trench gate electrode structure includes a metal or a metal compound.
